(19) United States
(12) Patent Application Publication
(10) Pub. No.: US 2015/0200639 A1
(43) Pub. Date: Jul. 16, 2015

(54) METHODS AND APPARATUS FOR LAYERED WAVEFORM AMPLITUDE VIEW OF MULTIPLE AUDIO CHANNELS

(71) Applicant: J. Todd Orler, Kirkland, WA (US)

(72) Inventor: J. Todd Orler, Kirkland, WA (US)

(21) Appl. No.: 11/832,951

(22) Filed: Aug. 2, 2007

(51) Int. Cl. H03G 3/00

(52) U.S. Cl. CPC H03G 3/002

(57) ABSTRACT

A system receives a plurality of waveforms. The system renders a graphical representation of the plurality of waveforms. The graphical representation includes an individual graphical representation for each of the waveforms in the plurality of waveforms, and a combined representation of the plurality of waveforms. The combined representation combines at least two of the plurality of waveforms in a single representation.

### BACKGROUND

Conventional technologies for audio files contain multiple channels. For a stereo file, there are two channels; a left channel, and a right channel. Conventional technologies for displaying multi-channel display the channels in a timeline display with each channel of audio in a separate display. The channels are usually stacked vertically, one below the next. Typically, the channels are displayed using the same colors.

Conventionally, when more than one channel of audio is to be displayed, for example, a stereo audio file, the audio channels are displayed stacked vertically, one below the next. In most cases, a stereo audio file is displayed with the left channel above the right channel. For greater numbers of channels, such as 5.1 channel (or 6-channel audio files), there are several common orders of channels. One common order for 5.1 channel audio files is: Left, Right, Center, LFE (Low Frequency Effect), Left surround, Right surround. In this scenario, the Left channel would be on top, followed by the Right channel, etc., with the Right surround channel on the bottom. Each channel is aligned along a timeline (i.e., a horizontal axis.) When playing audio in applications that display audio in a timeline, most applications display a vertical line, often referred to as a CTI (current time indicator) that shows the current play position. As the audio plays, the CTI travels to the right until it reaches the end of the audio. At the CTI, all audio channels are played simultaneously. In a conventional waveform amplitude display, in each channel's display region, the peak amplitude is displayed is at any given time along the timeline.

### SUMMARY

Conventional technologies for displaying channels as multiple waveforms suffer from a variety of deficiencies. In particular, conventional technologies for displaying multiple waveforms are limited in that displaying each channel stacked vertically reduces the number of pixels allocated to each channel since the total number of channels is displayed in the same size space whether there are two channels or six channels. For example, if there are 21 pixel rows available, and two channels to display, only 10 pixel rows are allotted to each channel, with the remaining pixel row assigned to the center line among two channels. This reduces the resolution visible for each channel. Conventional technologies are limited in that comparing multiple channels is difficult when the channels are stacked vertically. Additionally, identifying peak amplitude differences among multiple time-aligned channels is more challenging when the channels are separated vertically.

Embodiments disclosed herein significantly overcome such deficiencies and provide a system that includes a computer system executing a multiple waveforms displaying process that receives a plurality of waveforms, and layers each waveform (on top of the other waveforms) in a single waveform display. Each waveform is rendered in a different color with a percentage of transparency. Users viewing the waveforms can instantly identify differences and similarities among the waveforms. Additionally, rendering the multiple waveforms in a single waveform display allows for greater resolution. This allows users to see greater granularity differences and similarities among the waveforms.

In an example embodiment, the multiple waveforms displaying process determines the dimensions of a graphical region required to render the plurality of waveforms. The multiple waveforms displaying process determines a maximum and minimum amplitude from the plurality of waveforms, and a minimum sampling rate necessary to render the plurality of waveforms. The multiple waveforms displaying process creates a graphical region in which to display the graphical representation of the plurality of waveforms. The multiple waveforms displaying process proportionally resizes the graphical region such that the maximum possible resolution is displayed. The multiple waveforms displaying process renders each waveform in a distinct color (provided by a graphics engine). Each distinct color is rendered with an alpha transparency component that ranges from 0% to 100%. Each waveform is rendered as a plurality of pixels. An array of elements contains the color value for each pixel (that represents each waveform). In an example embodiment, a first waveform is represented in the array. For each subsequent waveform (in the plurality of waveforms), the color value for each pixel is blended with the color value currently in the array (from the first waveform represented in the array).

Each color value is determined by a red color component, green color component, blue color component and an alpha transparency value. The resulting graphical representation allows users to view the differences among the waveforms as well as areas (in the graphical representation) where the plurality of waveforms overlap. In another example embodiment, a user may apply editing and/or manipulation operations to the audio when presented in the layered view.

The multiple waveforms displaying process receives a plurality of waveforms, and renders a graphical representation of the plurality of waveforms. The graphical representation includes an individual graphical representation for each of the waveforms in the plurality of waveforms. The graphical representation includes a combined representation of the plurality of waveforms. The combined representation combines at least two of the plurality of waveforms in a single representation.

Other embodiments disclosed herein include any type of computerized device, workstation, handheld or laptop computer, or the like configured with software and/or circuitry (e.g., a processor) to process any or all of the method operations disclosed herein. In other words, a computerized device such as a computer or a data communications device or any type of processor that is programmed or configured to operate as explained herein is considered an embodiment disclosed herein.

Other embodiments disclosed herein include software programs to perform the steps and operations summarized above and disclosed in detail below. One such embodiment comprises a computer program product that has a computer-readable medium including computer program logic encoded thereon that, when performed in a computerized device having a coupling of a memory and a processor, programs the processor to perform the operations disclosed herein. Such arrangements are typically provided as software, code and/or other data (e.g., data structures) arranged or encoded on a computer readable medium such as an optical medium (e.g., CD-ROM), floppy or hard disk or other a medium such as firmware or microcode in one or more ROM or RAM or PROM chips or as an Application Specific Integrated Circuit (ASIC). The software or firmware or other such configurations can be installed onto a computerized device to cause the computerized device to perform the techniques explained as embodiments disclosed herein.

It is to be understood that the system disclosed herein may be embodied strictly as a software program, as software and hardware, or as hardware alone. The embodiments disclosed herein, may be employed in data communications devices and other computerized devices and software systems for such devices such as those manufactured by Adobe Systems Incorporated of San Jose, Calif.

### BRIEF DESCRIPTION OF THE DRAWINGS

The foregoing will be apparent from the following description of particular embodiments disclosed herein, as illustrated in the accompanying drawings in which like reference characters refer to the same parts throughout the different views. The drawings are not necessarily to scale, emphasis instead being placed upon illustrating the principles disclosed herein.

FIG. 1 illustrates an example of a traditional vertically stacked waveform display.

FIG. 2 illustrates an example of a layered waveform display, according to one embodiment disclosed herein.

FIG. 3 shows a high-level block diagram of a computer system according to one embodiment disclosed herein.

FIG. 4 illustrates a flowchart of a procedure performed by the system of FIG. 3, when the multiple waveforms displaying process receives a plurality of waveforms according to one embodiment disclosed herein.

FIG. 5 illustrates a flowchart of a procedure performed by the system of FIG. 3, when the multiple waveforms displaying process receives a plurality of waveforms, and identifies a sampling rate and a respective amplitude for each waveform in the plurality of waveforms, according to one embodiment disclosed herein.

FIG. 6 illustrates a flowchart of a procedure performed by the system of FIG. 3, when the multiple waveforms displaying process renders a graphical representation of the plurality of waveforms, according to one embodiment disclosed herein.

FIG. 7 illustrates a flowchart of a procedure performed by the system of FIG. 3, when the multiple waveforms displaying process renders a graphical representation of the plurality of waveforms, and for each waveform in the plurality of waveforms, renders an individual graphical representation in a distinct color comprising at least one color component, according to one embodiment disclosed herein.

FIG. 8 illustrates a flowchart of a procedure performed by the system of FIG. 3, when the multiple waveforms displaying process renders a graphical representation of the plurality of waveforms, and for each waveform in the plurality of waveforms, identifies a plurality of pixels that collectively represent the waveform, according to one embodiment disclosed herein.

FIG. 9 illustrates a flowchart of a procedure performed by the system of FIG. 3, when the multiple waveforms displaying process blends a plurality of colors to calculate the color value, the plurality of colors representing a color of each of the waveforms represented in each element of the array, according to one embodiment disclosed herein.

FIG. 10 illustrates a flowchart of a procedure performed by the system of FIG. 3, when the multiple waveforms displaying process overwrites the element of the array with the new color value and new alpha transparency value, according to one embodiment disclosed herein.

### DETAILED DESCRIPTION

Embodiments disclosed herein include a computer system executing a multiple waveforms displaying process that receives a plurality of waveforms, and layers each waveform (on top of the other waveforms) on a single waveform display. Each waveform is rendered in a different color with a percentage of transparency. Users viewing the waveforms can instantly identify differences and similarities among the waveforms. Additionally, rendering the multiple waveforms in a single waveform display allows for greater resolution. This allows users to see greater granularity differences and similarities among the waveforms.

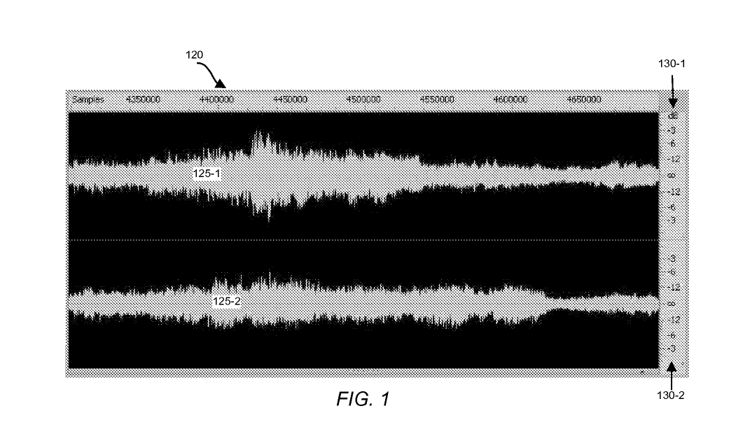

FIG. 1 illustrates a traditional vertically stacked waveform display with a first waveform 125-1 and a second waveform 125-2. The waveforms (i.e., the waveform 125-1 and the second waveform 125-2) are displayed on a single timeline ruler 120. The timeline ruler 120 denotes samples in time. However, each waveform (i.e., the waveform 125-1 and the second waveform 125-2) has their respective amplitude display 130-1 and 130-2.

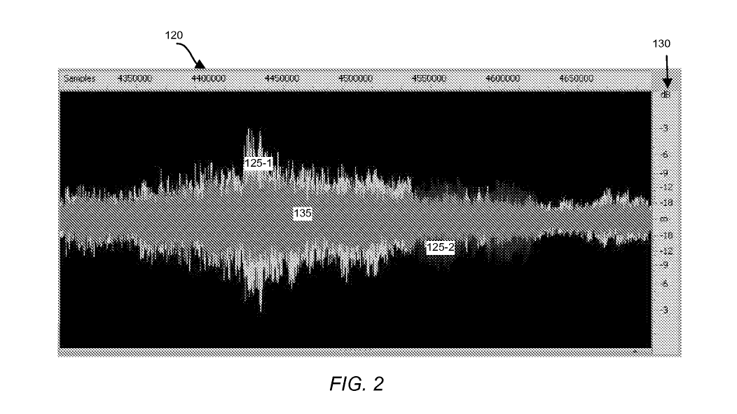

FIG. 2 illustrates an example layered waveform display according to embodiments disclosed herein. The graphical representation includes a sampling rate and a single amplitude display 130 (that is shared by all of the waveforms 125-N in the plurality of waveforms 125-N).

A first waveform 125-1 is layered over a second waveform 125-2. Each waveform 125-N is distinguishable over the other, including the areas 135 where the waveforms 125-N overlap.

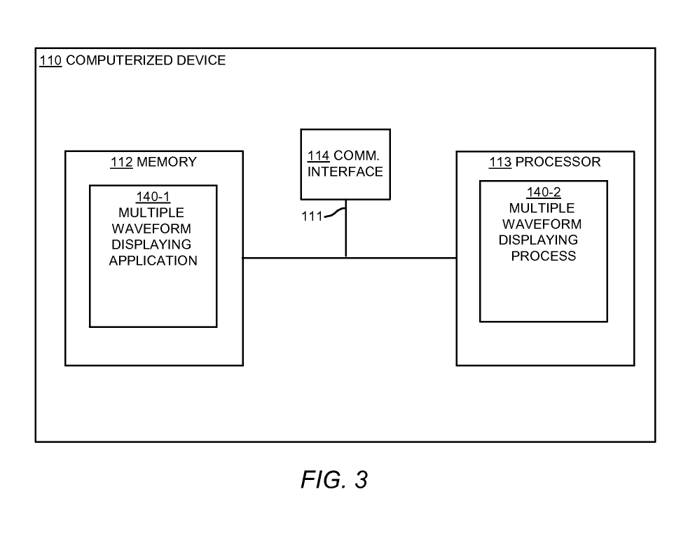

FIG. 3 illustrates an example architecture of a computer system 110 on which the multiple waveforms displaying process 140-2 operates. The computer system 110 may be any type of computerized device such as a personal computer, workstation, portable computing device, console, laptop, network terminal or the like. In this example, the computer system 110 includes an interconnection mechanism 111 that couples a memory system 112, a processor 113, and a communications interface 114. The communications interface 114 enables the computer system 110 to communicate with other devices (i.e., other computers) on a network (not shown). This can allow access to multiple waveforms displaying application 140-1 by remote computer systems.

The memory system 112 may be any type of computer readable medium that is encoded with an multiple waveforms displaying application 140-1 that may be embodied as software code such as data and/or logic instructions (e.g., code stored in the memory or on another computer readable medium such as a removable disk) that supports processing functionality according to different embodiments described herein. During operation of the computer system 110, the processor 113 accesses the memory system 112 via the interconnect 111 in order to launch, run, execute, interpret or otherwise perform the logic instructions of multiple waveforms displaying application 140-1. Execution of multiple waveforms displaying application 140-1 in this manner produces processing functionality in a multiple waveforms displaying process 140-2. In other words, multiple waveforms displaying process 140-2 represents one or more portions of runtime instances of multiple waveforms displaying application 140-1 (or the entire multiple waveforms displaying application 140-1) performing or executing within or upon the processor 113 in the computerized system 110 at runtime. It is to be understood that embodiments disclosed herein include the applications/software (i.e., the un-executed or non-performing logic instructions and/or data) encoded within a computer readable medium such as a floppy disk, hard disk or in an optical medium, or in a memory type system such as in firmware, read only memory (ROM), or, as in this example, as executable code within the memory system 112 (e.g., within random access memory or RAM). It is also to be understood that other embodiments disclosed herein can provide the applications/software operating within the processor 113 as the processes. While not shown in this example, those skilled in the art will understand that the computer system may include other processes and/or software and hardware components, such as an operating system, that have been left out of this illustration for ease of description.

Further details of configurations explained herein will now be provided with respect to a flow chart of processing steps that show the high level operations disclosed herein to perform the multiple waveforms displaying process 140-2.

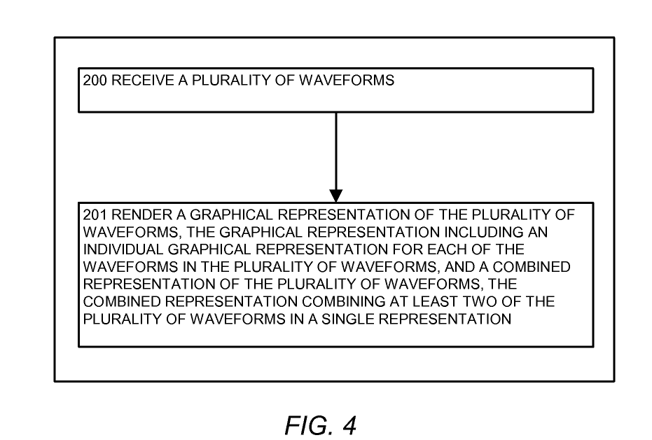

FIG. 4 is an embodiment of the steps performed by the multiple waveforms displaying process 140-2 when it receives a plurality of waveforms 125-N.

In step 200, the multiple waveforms displaying process 140-2 receives a plurality of waveforms 125-N. The multiple waveforms displaying process 140-2 receives a plurality of waveform files. Each waveform file represents the audio associated with a respective channel in, for example, a stereo.

In step 201, the multiple waveforms displaying process 140-2 renders a graphical representation of the plurality of waveforms 125-N. The graphical representation includes an individual graphical representation for each of the waveforms 125-N in the plurality of waveforms 125-N, and a combined representation of the plurality of waveforms 125-N. The combined representation combines at least two of the plurality of waveforms 125-N in a single representation. In other words, each of the waveforms 125-1 in the plurality of waveforms 125-N is layered on top of the other waveforms 125-2.

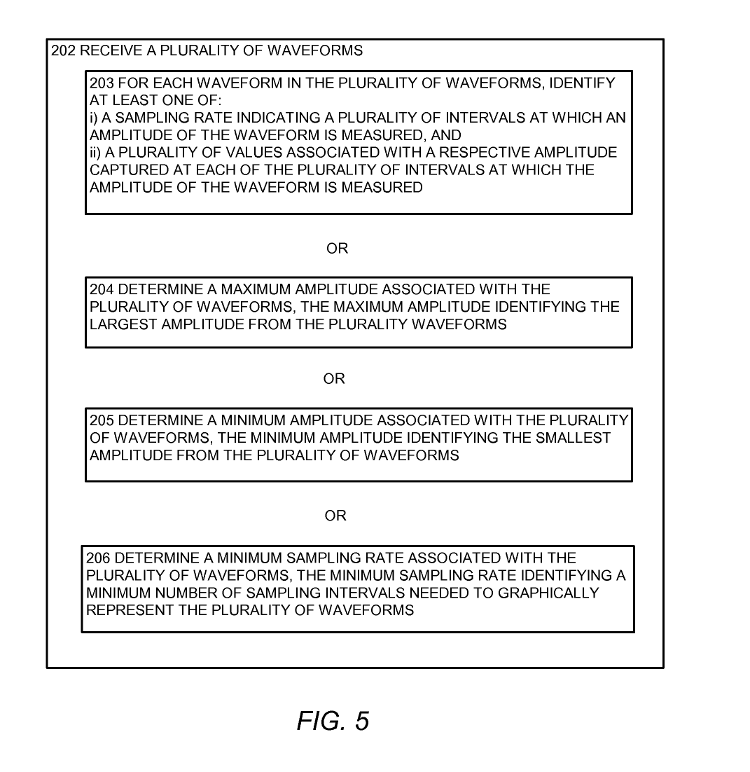

FIG. 5 is an embodiment of the steps performed by the multiple waveforms displaying process 140-2 when it receives a plurality of waveforms 125-N.

In step 202, the multiple waveforms displaying process 140-2 receives a plurality of waveforms 125-N. Each waveform 125-1 received has a respective sampling rate, maximum and minimum amplitude.

For each waveform in the plurality of waveforms 125-N, in step 203, the multiple waveforms displaying process 140-2, identifies at least one of:
i) a sampling rate indicating a plurality of intervals at which an amplitude of the waveform is measured, and
ii) a plurality of values associated with a respective amplitude captured at each of the plurality of intervals at which the amplitude of the waveform 125-N is measured.

In the graphical region in which the multiple waveforms displaying process 140-2 renders the graphical representation of the waveforms 125-N, the X axis displays the sampling rate, and the Y axis displays the amplitude(s) (i.e., the amplitude display 130) of the waveforms 125-N.

Alternatively, in step 204, the multiple waveforms displaying process 140-2 determines a maximum amplitude associated with the plurality of waveforms 125-N. The maximum amplitude identifies the largest amplitude from the plurality of waveforms 125-N. In an example embodiment, the multiple waveforms displaying process 140-2 identifies an individual maximum amplitude for each of the waveforms 125-N in the plurality of waveforms 125-N. The multiple waveforms displaying process 140-2 then identifies a maximum amplitude from the plurality of individual maximum amplitudes.

Alternatively, in step 205, the multiple waveforms displaying process 140-2 determines a minimum amplitude associated with the plurality of waveforms 125-N. The minimum amplitude identifies the smallest amplitude from the plurality of waveforms 125-N. In an example embodiment, the multiple waveforms displaying process 140-2 identifies an individual minimum amplitude for each of the waveforms 125-N in the plurality of waveforms 125-N. The multiple waveforms displaying process 140-2 then identifies a minimum amplitude from the plurality of individual minimum amplitudes.

Alternatively, in step 206, the multiple waveforms displaying process 140-2 determines a minimum sampling rate associated with the plurality of waveforms 125-N. The minimum sampling rate identifies a minimum number of sampling intervals needed to graphically represent the plurality of waveforms 125-N.

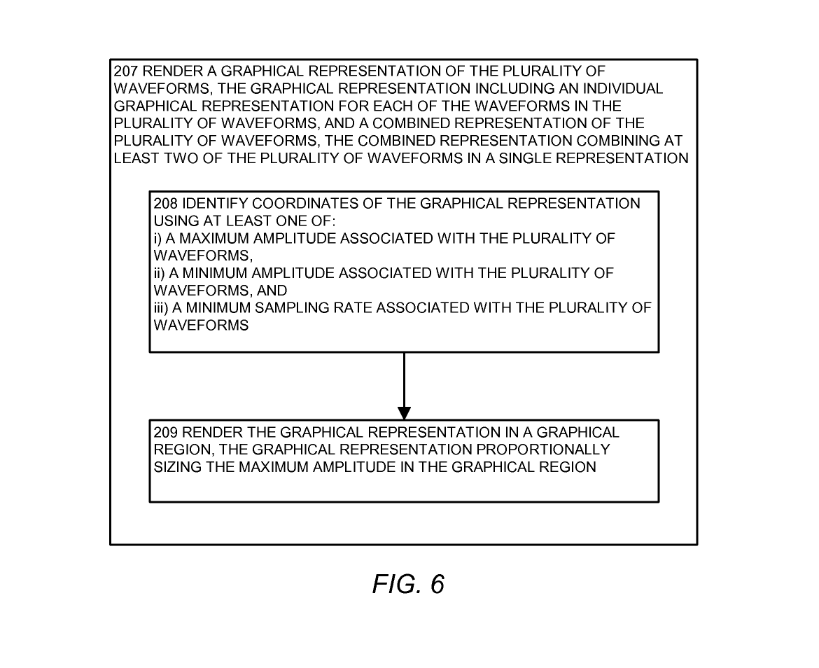

FIG. 6 is an embodiment of the steps performed by the multiple waveforms displaying process 140-2 when it renders a graphical representation of the plurality of waveforms 125-N.

In step 207, the multiple waveforms displaying process 140-2 renders a graphical representation of the plurality of waveforms 125-N. The graphical representation includes an individual graphical representation for each of the waveforms 125-N in the plurality of waveforms 125-N, and a combined representation of the plurality of waveforms 125-N. The combined representation combines at least two of the plurality of waveforms 125-N in a single representation. Essentially, the multiple waveforms displaying process 140-2 layers each of the waveform 125-1 in the plurality of waveforms 125-N in the graphical region in which the graphical representation is rendered.

In step 208, the multiple waveforms displaying process 140-2 identifies coordinates of the graphical representation using at least one of:
i) a maximum amplitude associated with the plurality of waveforms 125-N,
ii) a minimum amplitude associated with the plurality of waveforms 125-N, and
iii) a minimum sampling rate associated with the plurality of waveforms 125-N.
   The multiple waveforms displaying process 140-2 identifies the coordinates needed to render each of the waveform 125-1 in the plurality of waveforms 125-N, and then creates the graphical region in which the plurality of waveforms 125-N is rendered.

In step 209, the multiple waveforms displaying process 140-2 renders the graphical representation in a graphical region. The graphical representation proportionally sizes the maximum amplitude in the graphical region. The multiple waveforms displaying process 140-2 renders the graphical region to display the plurality of waveforms 125-N with the largest granularity possible for the plurality of waveforms 125-N.

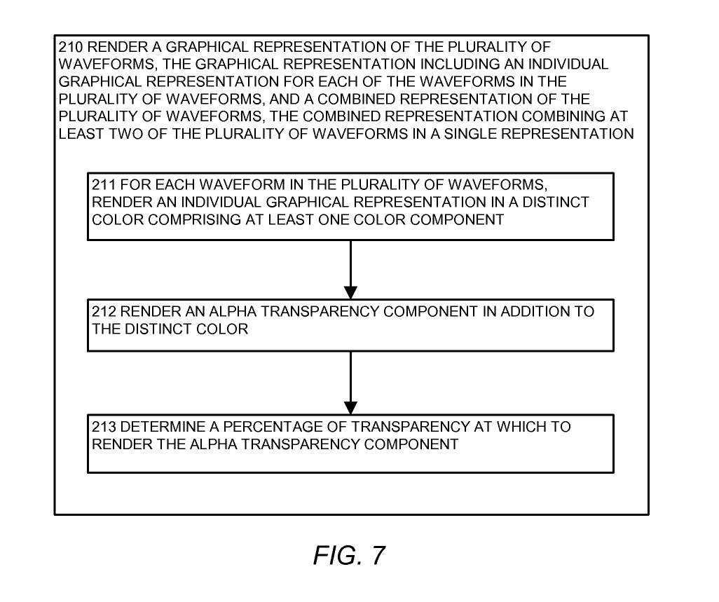

FIG. 7 is an embodiment of the steps performed by the multiple waveforms displaying process 140-2 when it renders a graphical representation of the plurality of waveforms 125-N.

In step 210, the multiple waveforms displaying process 140-2 renders a graphical representation of the plurality of waveforms 125-N. The graphical representation includes an individual graphical representation for each of the waveforms in the plurality of waveforms 125- N, and a combined representation of the plurality of waveforms 125-N. The combined representation combines at least two of the plurality of waveforms 125-N in a single representation.

For each waveform 125-1 in the plurality of waveforms 125-N, in step 211, the multiple waveforms displaying process 140-2 renders an individual graphical representation in a distinct color comprising at least one color component. The multiple waveforms displaying process 140-2 renders each waveform 125-1 in a distinct color. The distinct color is provided by a graphics engine. In an example embodiment, the distinct color is comprised of three components, red, green and blue.

In step 212, the multiple waveforms displaying process 140-2 renders an alpha transparency component in addition to the distinct color. The multiple waveforms displaying process 140-2 renders the distinct color with an alpha transparency component that adds a percentage of transparency (i.e., between 0% and 100%) to the distinct color such that, when the waveforms 125-N are layered upon each other, the common areas in the graphical representation are still visible to a user.

In step 213, the multiple waveforms displaying process 140-2 determines percentage of transparency at which to render the alpha transparency component. In an example embodiment, the multiple waveforms displaying process 140-2 determines the alpha transparency component is to be rendered at 50%, meaning that each distinct color that represents each of the waveforms 125-N in the plurality of waveforms 125-N is rendered with 50% transparency. Adding the alpha transparency component to the display of the waveform 125-1 renders the waveforms 125-N layered beneath the waveform 125-1 visible.

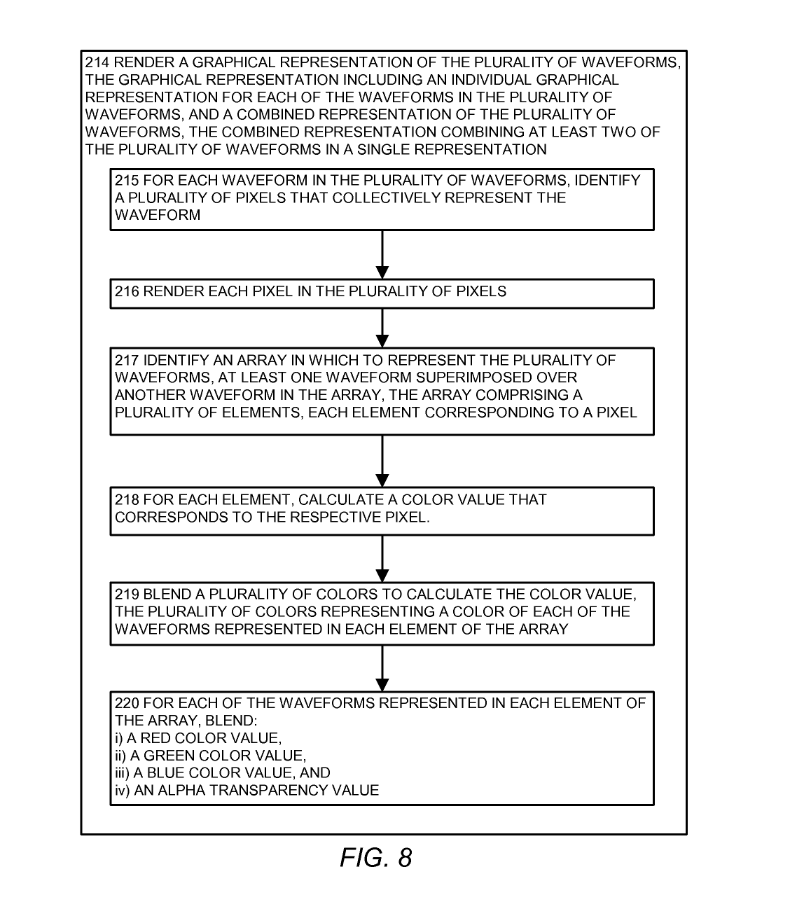

FIG. 8 is an embodiment of the steps performed by the multiple waveforms displaying process 140-2 when it renders a graphical representation of the plurality of waveforms 125-N.

In step 214, the multiple waveforms displaying process 140-2 renders a graphical representation of the plurality of waveforms 125-N. The graphical representation includes an individual graphical representation for each of the waveforms in the plurality of waveforms 125-N, and a combined representation of the plurality of waveforms 125-N. The combined representation combines at least two of the plurality of waveforms 125-N in a single representation.

For each waveform in the plurality of waveforms 125-N, in step 215, the multiple waveforms displaying process 140-2 identifies a plurality of pixels that collectively represents the waveform 125-1.

In step 216, the multiple waveforms displaying process 140-2 renders each pixel in the plurality of pixels. Each waveform 125-1 is represented in the graphical region by a plurality of pixels. Each pixel is rendered in a color (i.e., a red component, blue component and green component) along with an alpha transparency component.

In step 217, the multiple waveforms displaying process 140-2 identifies an array in which to represent the plurality of waveforms 125-N. At least one waveform is superimposed over another waveform in the array. The array comprises a plurality of elements. Each element corresponds to a pixel.

For each element (in the array), in step 218, the multiple waveforms displaying process 140-2 calculates a color value that corresponds to the respective pixel. For example, for the first waveform 125-1 that is rendered in the graphical region, the multiple waveforms displaying process 140-2 calculates a color value for those pixels that represent the waveform 125-1 (the black areas of the graphical region do not represent the waveform 125-1). In an example embodiment, the multiple waveforms displaying process 140-2 calculates a 0% alpha transparency component for the first waveform 125-1. In other words, the multiple waveforms displaying process 140-2 calculates the color value of the first waveform 125-1 with zero transparency. Any waveforms 125-N that are layered on top of that first waveform 125-1 are rendered with an alpha transparency component of greater than 0% such that the first waveform 125-1 is still visible beneath the other waveforms 125-N.

In step 219, the multiple waveforms displaying process 140-2 blends a plurality of colors to calculate the color value. The plurality of colors represents a color of each of the waveforms 125-N represented in each element of the array. After the color value of the first waveform 125-1 is calculated, the multiple waveforms displaying process 140-2 repeats the process of representing each waveform 125-N in the graphical region by a plurality of pixels. The multiple waveforms displaying process 140-2 begins with the first element in the array (that corresponds to the left most pixels of the graphical region), and blends the colors of the second waveform 125-2 with the color of the first waveform 125-1 (that is already represented in the array) until the last element of the array is reached. The last element of the array corresponds to the right most edge of the waveform 125-2 (or the end of the audio file). The multiple waveforms displaying process 140-2 continues this process until each of the waveforms 125-N in the plurality of waveforms 125-N is represented in the array.

For each of the waveforms 125-N represented in each element of the array, in step 220, the multiple waveforms displaying process 140-2 blends:
i) a red color value,
ii) a green color value,
iii) a blue color value, and
iv) an alpha transparency value.
   Each color is represented by a red component, a green component, a blue component, and an alpha transparency component that is represented as a percentage from 0% to 100%.

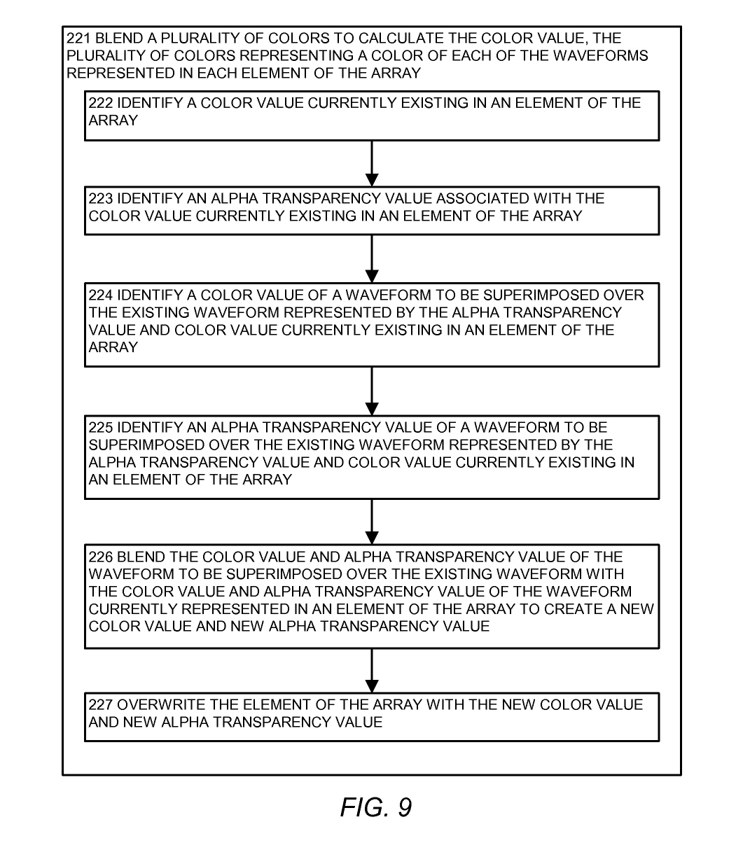

FIG. 9 is an embodiment of the steps performed by the multiple waveforms displaying process 140-2 when it blends a plurality of colors to calculate the color value.

In step 221, the multiple waveforms displaying process 140-2 blends a plurality of colors to calculate the color value. The plurality of colors represents a color of each of the waveforms represented in each element of the array. For example, the first waveform 125-1 has a color value of (1,0,0) and an alpha transparency value of 50%. The second waveform 125-2 has a color value of (0,1,0) and an alpha transparency value of 50%. The multiple waveforms displaying process 140-2 blends these two waveforms (i.e., waveform 125-1 and waveform 125-2) to create a color value of (1,1,0).

In step 222, the multiple waveforms displaying process 140-2 identifies a color value currently existing in an element of the array. In an example embodiment, the multiple waveforms displaying process 140-2 has already calculated the color value of at least one waveform 125-1 in the array. The multiple waveforms displaying process 140-2 identifies the current color identified in the element of the array.

In step 223, the multiple waveforms displaying process 140-2 identifies an alpha transparency value associated with the color value currently existing in an element of the array. For example, the multiple waveforms displaying process 140-2 identifies that the alpha transparency value associated with the color value is 50%.

In step 224, the multiple waveforms displaying process 140-2 identifies a color value of a waveform 125-2 to be superimposed over the existing waveform 125-1 represented by the alpha transparency value and color value currently existing in an element of the array. A graphics engine generates the color value of the waveform 125-2 to be superimposed over the existing waveform 125-1.

In step 225, the multiple waveforms displaying process 140-2 identifies an alpha transparency value of a waveform 125-2 to be superimposed over the existing waveform 125-1 represented by the alpha transparency value and color value currently existing in an element of the array. For example, the alpha transparency value may be set to anywhere between 0% and 100%.

In step 226, the multiple waveforms displaying process 140-2 blends the color value and alpha transparency value of the waveform 125-2 to be superimposed over the existing waveform 125-1 with the color value and alpha transparency value of the waveform 125-1 currently represented in an element of the array to create a new color value and new alpha transparency value.

In step 227, the multiple waveforms displaying process 140-2 overwrites the element of the array with the new color value and new alpha transparency value. The multiple waveforms displaying process 140-2 repeats this process for each waveform 125-1 in the plurality of waveforms 125-N. As each new waveform 125-1 is blended in with the existing waveforms 125-N, the multiple waveforms displaying process 140-2 overwrites the elements in the array with the new composite color value.

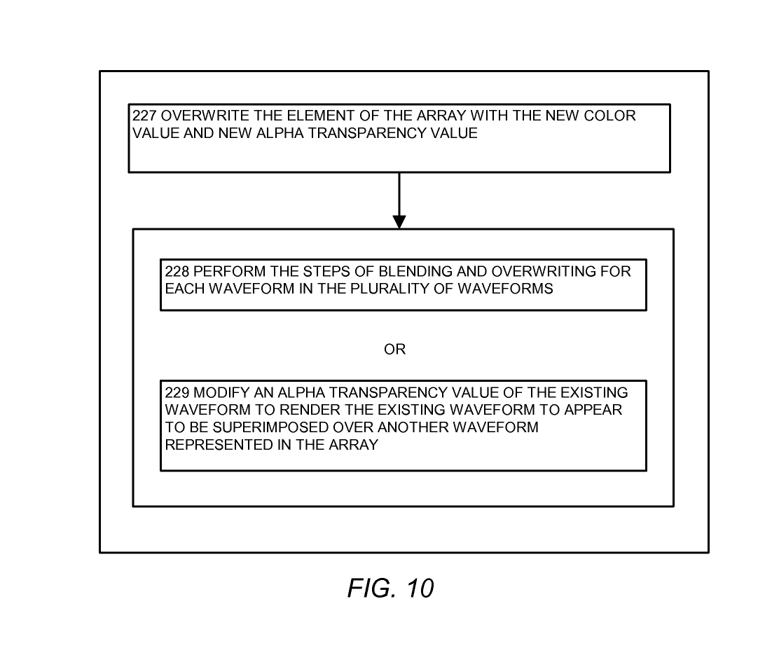

FIG. 10 is a continuation of FIG. 9 of an embodiment of the steps performed by the multiple waveforms displaying process 140-2 when it overwrites the element of the array with the new color value and new alpha transparency value.

In step 228, the multiple waveforms displaying process 140-2 performs the steps of blending and overwriting for each waveform in the plurality of waveforms 125-N. Each waveform 125-1 in the plurality of waveforms 125-N is blended into each element in the array such that when the plurality of waveforms 125-N is rendered as the graphical representation, each waveform 125-1 is distinguishable from the other waveforms 125-N and the areas 135 where the plurality of waveforms 125-N overlap is also distinguishable.

Alternatively, in step 229, the multiple waveforms displaying process 140-2 modifies an alpha transparency value of the existing waveform 125-1 to render the existing waveform 125-1 to appear to be superimposed over another waveform 125-2 represented in the array. The multiple waveforms displaying process 140-2 may alter the alpha transparency value of an existing waveform 125-1 to render that waveform 125-1 in the foreground of the graphical representation. In other words, once a waveform 125-1 is rendered in the array of elements, the multiple waveforms displaying process 140-2 may modify the alpha transparency value to make the waveform 125-1 appear to be in the foreground of the graphical representation as compared to the other waveforms 125-N.

While computer systems and methods have been particularly shown and described above with references to configurations thereof, it will be understood by those skilled in the art that various changes in form and details may be made therein without departing from the scope disclosed herein. Accordingly, the information disclosed herein is not intended to be limited by the example configurations provided above.

1. A computer implemented method comprising:
accessing data representing a plurality of waveforms, each waveform representing a channel of audio data; and
rendering a layered representation of the plurality of waveforms in an editing interface on a display screen, the editing interface configured to receive edits to the audio data,
wherein, in the layered representation, the plurality of waveforms are rendered overlapping one another along a shared axis shared by each of the plurality of waveforms,
wherein rendering the layered representation comprises:
determining a minimum sampling rate associated with the plurality of waveforms, and
rendering the shared axis for the layered representation having a first plurality of coordinates based on the minimum sampling rate.

2. The method of claim 1, further comprising:
for each waveform in the plurality of waveforms, identifying at least one of:
the sampling rate indicating a plurality of intervals at which an amplitude of the waveform is measured; and
a plurality of values associated with a respective amplitude, captured at each of the plurality of intervals at which the amplitude of the waveform is measured.

3. The method of claim 1, further comprising determining a maximum amplitude associated with the plurality of waveforms by comparing respective amplitudes of the plurality of waveforms to determine the largest amplitude from the plurality of waveforms.

4. The method of claim 1, further comprising determining a minimum amplitude associated with the plurality of waveforms by comparing respective amplitudes of the plurality of waveforms to determine the smallest amplitude from the plurality of waveforms.

5. (canceled)

6. The method of claim 1 wherein rendering the layered representation further comprises:
determining a maximum amplitude associated with the plurality of waveforms by comparing respective amplitudes of the plurality of waveforms to determine the largest amplitude from the plurality of waveforms; and
rendering an additional shared axis for the layered representation having a second plurality of coordinates, the layered representation proportionally sizing the maximum amplitude in a graphical region in which the layered representation is rendered.

7. (canceled)

8. The method of claim 1 wherein each waveform in the plurality of waveforms is rendered in a distinct color comprising at least one color component.

9-18. (canceled)

19. A computerized device comprising:
a memory;
a processor;
a communications interface;
a display screen; and
an interconnection mechanism coupling the memory, the processor and the communications interface;
wherein the processor is configured to executed an editing application encoded on the memory to render an editing interface on the display screen, the interface comprising:
a layered representation of a plurality of waveforms,
wherein, in the layered representation of the plurality of waveforms on the display screen, the plurality of waveforms are displayed on top of one another along a shared axis and the layered representation comprises a region in which the plurality of waveforms overlap with each other,
wherein rendering the layered representation comprises:
determining a minimum sampling rate associated with the plurality of waveforms, and
rendering the shared axis for the layered representation having a first plurality of coordinates based on the minimum sampling rate.

20. A computer program product comprising a computer-readable storage medium having instructions stored thereon for processing data information, the instructions comprising:
instructions that configure a computing device to access audio data comprising a plurality of waveforms, each waveform representing a different audio channel; and
instructions that configure the computing device to render an interface configured to receive input editing the audio data and comprising a layered representation of the plurality of waveforms, the layered representation depicting each of the plurality of waveforms along a shared axis and overlapping one another,
wherein rendering the layered representation comprises:
determining a minimum sampling rate associated with the plurality of waveforms,
rendering the shared axis for the layered representation having a first plurality of coordinates based on the minimum sampling rate, and
determining a maximum amplitude associated with the plurality of waveforms,
wherein, in the layered representation, each of the plurality of waveforms is rendered using a different color and the layered representation indicates a region in which the plurality of waveforms overlap with each other by rendering the overlapping region using a blended value of the plurality of waveforms that overlap,
wherein the blended value is determined using at least one of a color value of each of the plurality of waveforms that overlap or an alpha transparency value of each of the plurality of waveforms that overlap.

21-26. (canceled)

27. The method of claim 8,
wherein rendering the layered representation comprises blending a color component of a first waveform and a color component of a second waveform at portions in which the first waveform and second waveform overlap.

28. The method of claim 1,
wherein rendering the layered representation comprises blending a plurality of color components of each of the plurality of waveforms.

29. The method of claim 28, wherein blending comprises blending a red color component, a green color component, and a blue color component of each of the plurality of waveforms.

30. The method of claim 28, wherein blending further comprises blending an alpha transparency value of each of the plurality of waveforms.

31. The method of claim 8,
wherein rendering the layered representation comprises blending an alpha transparency value of a first waveform and an alpha transparency value of a second waveform at portions in which the first waveform and second waveform overlap.

32. The method of claim 1 wherein a first waveform of the plurality of waveforms is rendered using a first alpha transparency level and a second waveform of the plurality of waveforms is rendered using a second alpha transparency value.

33. The method of claim 1, wherein the layered representation defines a foreground and the method further comprises:
changing an alpha transparency level of a selected one of the plurality of waveforms to move the selected one of the plurality of waveforms to the foreground of the layered representation.

34. The system of claim 19, wherein each of the plurality of waveforms is displayed using a different color.

35. The system of claim 34,
wherein the plurality of waveforms are displayed using the different color outside the region in which the plurality of waveforms overlap, and
wherein rendering the interface comprises blending a color component of a first waveform and a color component of a second waveform in the region in which the plurality of waveforms overlap.

36. The system of claim 35, wherein blending comprises blending a red color component, a green color component, and a blue color component of each of the plurality of waveforms.

37. The system of claim 19, wherein, rendering the interface comprises blending an alpha transparency value of each of the plurality of waveforms.

38. The system of claim 19, wherein the editing interface is configured to receive an edit to the audio data.

39. The system of claim 19, wherein the layered representation defines a foreground and the method further comprises:
changing an alpha transparency level of a selected one of the plurality of waveforms to move the selected one of the plurality of waveforms to the foreground of the layered representation.

40. The computer program product of claim 20, wherein the interface is configured to receive input to move a selected one of the plurality of waveforms to a foreground of the layered representation.
